(19) United States
(12) Patent Application Publication
(10) Pub. No.: US 2010/0294641 A1
(43) Pub. Date: Nov. 25, 2010

(54) Sanitary Fitting With an Electrical Operating Device, Which has at Least One Capacitive Sensor

(76) Inventor: Horst Kunkel, Stuttgart (DE)

Correspondence Address: FACTOR & LAKE, LTD, 1327 W. WASHINGTON BLVD., SUITE 5G/H, CHICAGO, IL, 60607, US

(21) Appl. No.: 11/917,981

(22) PCT Filed: May 24, 2006
(86) PCT No.: PCT/EP06/04920

§ 371 Date: Dec. 18, 2007

(30) Foreign Application Priority Data
Jun. 21, 2005 (DE) 10 2005 028 599.6

(51) Int. Cl. H03K 17/975

(52) U.S. Cl. 200/600

(57) ABSTRACT

The invention describes a sanitary fitting with an electrical operating device, which has at least one capacitive sensor (1) with at least one operating region (3). The operating region (3) comprises a support layer (7), which is composed of an electrically insulating material, and an at least partially electrically conductive sensor layer (9) which is functionally connected to an electrical control unit. The sensor layer (9) is arranged on that side of the support layer (7) which is remote from an operating side of the operating region (3), and is connected to the control unit via an electrically conductive conduction layer (23).

The invention relates to a sanitary fitting with an electrical actuating device which exhibits at least one capacitive sensor with at least one actuating region, the actuating region exhibiting a carrier layer, consisting of an electrically insulating material, and an at least partially electrically conductive sensor layer which is functionally connected to an electrical control unit.

In known sanitary fittings, actuating/detecting regions that are constructed in the form of layers are employed for capacitive sensors. With the sensors, in particular the temperature of the water and/or the volumetric flow-rate of the water issuing from the sanitary fitting can be adjusted. Other functional components of the sanitary fitting—for example, lighting means—can also be actuated with the sensors. The actuating/detecting regions have to be made, at least in part, of electrically conductive material that has no galvanic connections to the external surface of the sanitary fitting. Furthermore, the lamellar structure should not exhibit any inclusions—in particular, inclusions of air—by which the actuation sensitivity of the sensor would be impaired. In addition, it is desirable that the sanitary fittings with the actuating/detecting regions exhibit an appealing exterior.

It is known to apply sensor surfaces onto smooth upper surfaces, in particular glass or acrylic glass. However, these sensor surfaces are comparatively sensitive to mechanical stress. For this reason, vapour-deposited aluminium surfaces, in particular, cannot be contacted directly. On the contrary, they even require a further protection against contact, since otherwise they can be very easily damaged. They are therefore unsuitable for use in the sanitary field, where they are actuated frequently and, moreover, exposed to variable external influences, in particular moisture, cleaning agent and fluctuations in temperature.

The object of the present invention is to configure a sanitary fitting of the type specified in the introduction in such a way that the sensors also withstand intense loads, in particular mechanical loads, and, furthermore, the sanitary fitting exhibits a visually appealing exterior.

In accordance with the invention, this object is achieved by the sensor layer being arranged on the side of the carrier layer facing away from an actuating side of the actuating region and being connected to the control unit via an electrically conductive conduction layer.

In accordance with the invention, the sensor is accordingly outwardly protected against external influences, electrically and mechanically, by means of the carrier layer. The sensor layer preferably ‘clings’ to the carrier layer. This has the advantage that an almost air-free connection arises between the external surface of the sensor and the sensor layer, and in this way the sensor exhibits a high capacitive sensitivity, so that it can be actuated without the sensor layer being touched at all. The contacting of the sensor layer in the direction of the control unit is effected via the conduction layer.

In a particularly advantageous embodiment, the sensor layer can be capacitively connected to the conduction layer. This has the advantage that the sensor layer, which is difficult to contact, is integrated capacitively and in this way is provided with at least one contactless, non-galvanic connection to the control unit.

In expedient manner, the sensor layer can be arranged directly on the carrier layer, and the conduction layer can be arranged on the side of the sensor layer facing away from the carrier layer, and the sensor layer can be galvanically isolated from the conduction layer. The conduction layer is preferably adapted to the contours of the sensor layer, so that an optimal capacitive transmission is made possible.

The sensor layer and the conduction layer may form the plates of a capacitor, and the conduction layer may be galvanically connected to the control unit. In this way the capacitance can be reproducibly preset at the factory.

In order to enhance the responsiveness of the sensor, a dielectric having a high relative permittivity—in particular, a gel or a highly flexible adhesive—may be arranged between the sensor layer and the conduction layer. This has the advantage that the content of air can, on account of its low relative permittivity, be kept relatively low, since at most a small air gap remains. Gel and adhesive by way of dielectric have the advantage that no mechanical load originates from them.

The conduction layer may be made of brass, which is a very good electrical conductor and enables a good—in particular, corrosion-resistant—galvanic connection.

In another particularly advantageous embodiment, the conduction layer can be galvanically connected to the sensor layer. This has the advantage that a reliable contacting is realised which, in particular, is largely unsusceptible to electromagnetic perturbing influences in the sanitary fitting.

In order to obtain a small total thickness of the sensor, the conduction layer—in particular, a transparent conductive glass coating—can be arranged directly on the carrier layer, and the sensor layer can be arranged on the side of the conduction layer facing away from the carrier layer. A transparent conduction layer—in particular a transparent glass coating, for example ITO—on a transparent carrier layer makes it possible for the sensor layer—which, where appropriate, is metallically specular—to be visible from the actuating side, positively influencing the visual impression of the sanitary fitting.

In order to avoid perturbing inclusions of air, the sensor layer can be arranged directly on the conduction layer. This enables, furthermore, a reliable contacting of the sensor layer. In preferred manner, a transparent electrically conductive coating for glass or materials of such a type may have been applied onto the carrier layer made of glass or material of such a type, and a connection to a conducting sensor layer, which, in particular, has been vapour-deposited on said coating, may be established galvanically.

In visually particularly appealing and very robust manner, the carrier layer may be made of a use-resistant material having a smooth upper surface for applying the sensor layer; in particular, it may be made of glass, porcelain or plastic, in particular crystal-clear plastic such as acrylic glass or polycarbonate.

In order to minimise inclusions of air having an attenuating effect, the sensor layer may be a surface that has been vapour-coated with metal, in particular with aluminium or silver. Vapour-deposited surfaces are, furthermore, not thickly applied and realise a capacitor plate in technically simple manner. Vapour-deposited metals are good conductors and enable a good capacitive coupling. In addition, a visually appealing specular upper surface of the sensor is realised by vapour deposition of the conduction layer consisting of aluminium or silver onto the transparent carrier layer. Other metals may also have been vapour-deposited which, when applied appropriately, act as colour filters, for example, and therefore reflect only an appropriate colour spectrum.

By way of additional protection, in particular against oxidation, the sensor layer may have been covered on its side facing away from the carrier layer with a protective layer, in particular with a dielectric protective lacquer.

In a manner that is reliable, robust and very efficiently electrically conducting, the conduction layer may be connected to the electrical control unit indirectly, in particular via a mounting-plate, or directly, in particular with at least one spring-loaded contact and/or with at least one soldered joint and/or with at least one conducting rubber and/or with at least one self-adhesive copper binder (copper adhesive tape). In particular, conducting transparent glass coatings—for example, ITO surfaces—can be contacted very easily with conducting rubber or with self-adhesive copper binders.

In order to achieve an appealing visual design, the upper surface of the actuating region may be flat or curved. A curved upper surface has the advantage, moreover, that it can be grasped better in tactile manner.

Some embodiments of the invention will be elucidated in more detail in the following on the basis of the drawing; shown are:

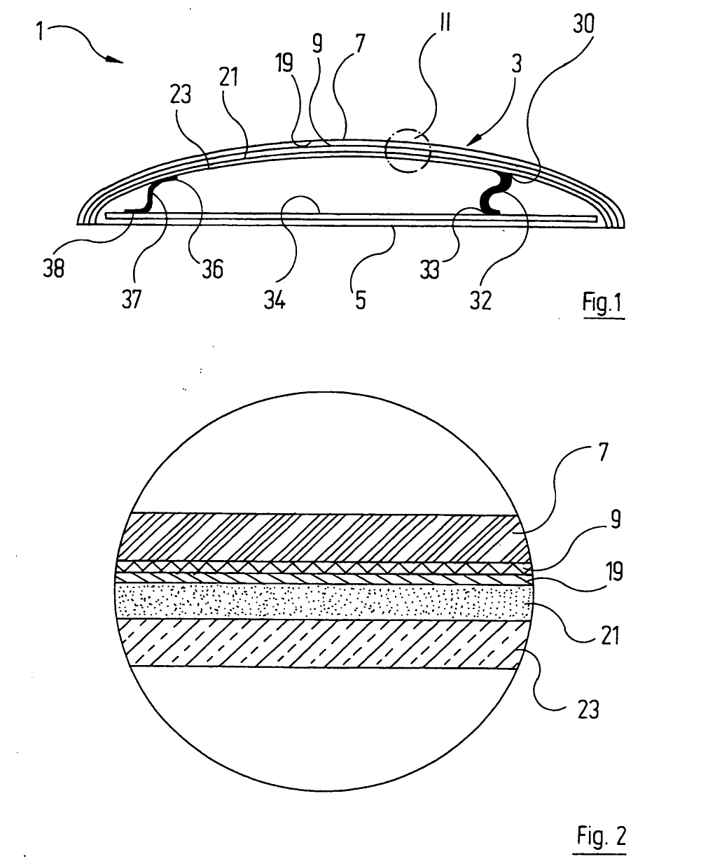

FIG. 1 schematically in cross-section, a capacitive sensor of an actuating device for a sanitary fitting with a curved actuating region, wherein a sensor layer is capacitively connected to a conduction layer;

FIG. 2 schematically, a detail of the sensor layer and of the conduction layer according to FIG. 1 in region II therein;

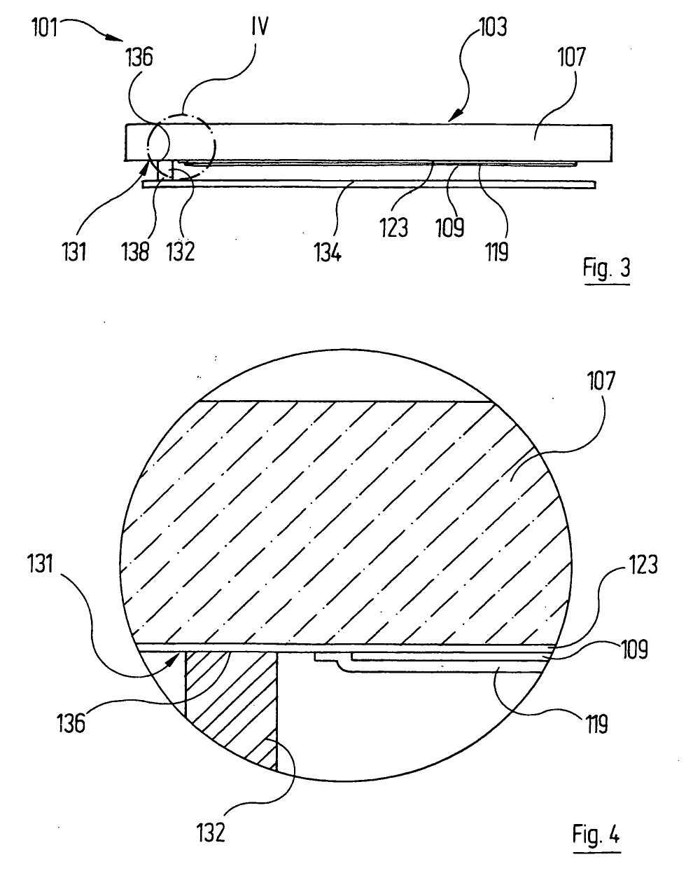

FIG. 3 schematically in cross-section, a capacitive sensor of an actuating device for a sanitary fitting with a flat actuating region, wherein a sensor layer is galvanically connected to a conduction layer;

FIG. 4 schematically, a detail of the sensor layer and of the conduction layer according to FIG. 3 in region IV therein.

A capacitive sensor, provided overall with reference symbol 1, of an electrical actuating device—which is not represented—of a sanitary fitting is shown in cross-section in FIG. 1. With the actuating device the temperature of the water and/or the volumetric flow-rate of the water issuing from the sanitary fitting can be adjusted via a mixing valve which is not represented.

By way of actuating region the sensor 1 is provided with a lenticular sensor hood 3 having an external surface that is convexly curved, observed from an actuating side at the top in FIG. 1. The sensor hood 3 terminates at the bottom with a flat bottom surface 5.

The sensor hood 3 exhibits a lamellar structure consisting of a plurality of different layers, each with homogeneous layer thickness over the entire surface of the sensor hood 3, all the layers elucidated in more detail in the following extending over the entire surface of the sensor hood 3. The lamellar structure is represented in detail in FIG. 2.

In FIGS. 1, 2 a carrier layer 7 consisting of electrically insulating, transparent glass is provided by way of uppermost, external protective layer. Onto said carrier layer an electrically conductive sensor layer 9 consisting of aluminium is directly vapour-deposited from below—that is to say, on the side facing away from the actuating side of the sensor hood 3.

In FIG. 1 the sensor layer 9 has been covered from below on its side facing away from the carrier layer 7 with a layer consisting of dielectric protective lacquer 19.

The protective lacquer 19 is adjoined by a layer consisting of a dielectric gel 21 having a high relative permittivity, on which an electrically conductive conduction layer 23 consisting of brass is arranged from below, on the side of the sensor layer 9 facing away from the carrier layer 7.

The sensor layer 9 and the conduction layer 23 form the plates of a capacitor, which are galvanically isolated from one another by the protective lacquer 19 and the gel 21 by way of dielectric. The sensor layer 9 is consequently capacitively connected to the conduction layer 23.

On the right in FIG. 1 the conduction layer 23 is connected to a signal line 32 via a soldered joint 30. The signal line 32 leads to a contact 33 pertaining to a flat mounting-plate 34.

The conduction layer 23 may alternatively—as represented on the left in FIG. 1—be galvanically connected to a contact 38 pertaining to the mounting-plate 34 from below via a spring-loaded contact 36 of a spring 37 consisting of electrically conductive material.

The mounting-plate 34 is arranged above the bottom surface 5, parallel to the latter, within the region delimited by the sensor hood 3.

From the mounting-plate 34 a control line—which is not shown—leads to the electrical control unit which in this way is functionally connected to the sensor layer 9 directly.

Capacitive changes in the sensor 1 in the event of contact, for example with a finger, are registered by the control unit, and the mixing valve is driven accordingly.

For the purpose of actuating the sensor 1, it is sufficient if the sensor hood 3 is touched from the actuating side, for example with a finger.

Instead of, or in addition to, the gel 21, a different dielectric having a high relative permittivity—for example, a highly flexible adhesive—may be arranged between the sensor layer 9 and the conduction layer 23. In addition to or instead of this, a minimal air gap may also have been provided.

In a second embodiment, represented in FIG. 3 and in FIG. 4 in detail, those elements which are similar to those of the first exemplary embodiment, described in FIG. 1 and FIG. 2, have been provided with the same reference symbols plus 100, so that, with respect to the description thereof, reference is made to the remarks relating to the first exemplary embodiment. This exemplary embodiment differs from the first by virtue of the fact that the sensor 101 is not curved but flat.

Also, a bottom surface 5 as in the first exemplary embodiment has been dispensed with here. The conduction layer 123 is not connected to a sensor layer 109 capacitively, but galvanically. A dielectric layer between the conduction layer 123 and the sensor layer 109 is therefore dispensed with.

The conduction layer 123 is a transparent electrically conductive coating, preferably an ITO layer, which in FIGS. 3, 4 has been directly applied from below onto a carrier layer 107 consisting of glass.

The sensor layer 109 is aluminium which has been directly vapour-deposited onto the side of the conduction layer 123 facing away from the carrier layer 107. In this way the sensor layer 109 and the conduction layer 123 form a capacitor plate of the capacitive sensor 101.

In FIGS. 3, 4 the sensor layer 109 has been covered from below on its side facing away from the carrier layer 107 with a layer of protective lacquer 119. The sensor layer 109 does not extend over the entire lower surface of the conduction layer 123, so that on the underside thereof an edge 131 which has not been vapour-coated with aluminium remains bare.

Within this bare edge 131—on the left in FIGS. 3, 4—a substantially right-parallelipipedal conducting rubber 132 consisting of electrically conducting material forms with its upper end face a contact 136 with the underside of the conduction layer 123.

The conducting rubber 132 leads vertically downwards to a contact 138 on a flat mounting-plate 134 arranged parallel to the sensor hood 103. The conducting rubber 132 forms a galvanic connection between the conduction layer 123 and the mounting-plate 134.

The mounting-plate 134 is in turn connected, in a manner analogous to the first exemplary embodiment, to a control unit which is not represented. Actuation of the sensor 101 is effected in a manner analogous to the first exemplary embodiment.

In both exemplary embodiments, instead of being made of glass the carrier layer 7; 107 may also be made of a different electrically insulating, use-resistant material having a smooth upper surface for applying the sensor layer 9, 109, in particular consisting of porcelain or plastic, in particular crystal-clear plastic such as acrylic glass or polycarbonate.

Instead of being flat or convexly curved, the upper surface of the sensor hood 3; 103 may also be curved in arbitrarily different manner, for example concavely.

Instead of being a surface that has been vapour-coated with aluminium, the sensor layer 9; 109 may also be a different conductive layer which, viewed through the transparent carrier layer 7; 107, results in an aesthetic appearance.

Instead of aluminium, a different metal—silver, for example—may also have been vapour-deposited by way of sensor layer 9; 109. Metals may also have been vapour-deposited that, when applied appropriately, act as colour filters, for example, and therefore reflect only an appropriate colour spectrum.

Instead of being connected with a spring-loaded contact 36 of a spring 37, with a signal line 32 with a soldered joint 30, or with a conducting rubber 132, the conduction layer 23; 123—or rather the sensor layer 9—may also have been connected to the electrical control unit with self-adhesive copper binders (copper adhesive tape) indirectly, in particular via the mounting-plate 34; 134, or directly, doing without a mounting-plate 34; 134.

Instead of the mixing unit for adjusting the temperature of the water and/or the volumetric flow-rate of the water, other components of the sanitary fitting—for example, a lighting means and/or a mist-generator—may also be actuated with the actuating device.

1. A sanitary fitting with an electrical actuating device which exhibits at least one capacitive sensor with at least one actuating region, the actuating region exhibiting a carrier layer, including an electrically insulating material, and an at least partially electrically conductive sensor layer which is functionally connected to an electrical control unit,
wherein
the sensor layer is arranged on the side of the carrier layer facing away from an actuating side of the actuating region and is connected to the control unit via an electrically conductive conduction layer.

2. The sanitary fitting of claim 1, wherein the sensor layer is capacitively connected to the conduction layer.

3. The sanitary fitting of claim 1, wherein the sensor layer is arranged directly on the carrier layer, and the conduction layer is arranged on the side of the sensor layer facing away from the carrier layer, and the sensor layer is galvanically isolated from the conduction layer.

4. The sanitary fitting of claim 1, wherein the sensor layer and the conduction layer form the plates of a capacitor, and the conduction layer is galvanically connected to the control unit.

5. The sanitary fitting of claim 1, further comprising a dielectric having a high relative permittivity being arranged between the sensor layer and the conduction layer.

6. The sanitary fitting of claim 1, wherein the conduction layer is made of brass.

7. The sanitary fitting of claim 1, wherein the conduction layer is galvanically connected to the sensor layer.

8. The sanitary fitting of claim 1, wherein the conduction layer is arranged directly on the carrier layer, and the sensor layer is arranged on the side of the conduction layer facing away from the carrier layer.

9. The sanitary fitting of claim 1, wherein the sensor layer is arranged directly on the conduction layer.

10. The sanitary fitting of claim 1, wherein the carrier layer is made of a use-resistant material having a smooth upper surface for applying the sensor layer.

11. The sanitary fitting of claim 1, wherein the sensor layer is a surface that has been vapour-coated with metal.

12. The sanitary fitting of claim 1, wherein the sensor layer is covered on its side facing away from the carrier layer with a protective layer.

13. The sanitary fitting of claim 1, wherein the conduction layer is connected to the electrical control unit indirectly, or directly.

14. The sanitary fitting according of claim 1, wherein the upper surface of the actuating region is flat or curved.

15. The sanitary fitting of claim 10, wherein the use-resistant material is made of glass, porcelain, or plastic.

16. The sanitary fitting of claim 15, wherein the plastic is crystal-clear plastic, acrylic glass, or polycarbonate.

17. The sanitary fitting of claim 12, wherein the protective layer is a dielectic protective lacquer.

18. The sanitary fitting of claim 13, wherein the conduction layer indirectly connected to the electrical control unit is via a mounting plate.

19. The sanitary fitting of claim 13, wherein the conductive layer directly connected to the electrical control unit is via at least one spring-loaded contact, and/or at least one soldered joint, and/or at least one conducting rubber, and/or at least one self-adhesive copper binder.

20. The sanitary fitting of claim 19, wherein the self-adhesive copper binder is a copper adhesive tape.
